(19) United States
(12) Patent Application Publication
(10) Pub. No.: US 2026/0252770 A1
(43) Pub. Date: Aug. 27, 2026

(54) METHOD AND DEVICE WITH TANGENT PLANE DISTANCE ESTIMATION

(71) Applicant: AVEVA Software LLC, Lake Forest, CA (US)

(72) Inventors: Gang XU, Irvine, CA (US); Zhenghao LI, Mountain View, CA (US); Yuanyuan LYU, Irvine, CA (US)

(73) Assignee: AVEVA Software LLC, Lake Forest, CA (US)

(21) Appl. No.: 19/065,618

(22) Filed: Feb. 27, 2025

(51) Int. Cl. G06F 30/28

(52) U.S. Cl. CPC G06F 30/28

(57) ABSTRACT

In one general aspect, a method is performed by a computing device comprising storage hardware and processing hardware. The storage hardware stores instructions configured to cause the processing hardware to perform the method. The method includes: accessing a process model stored in the storage hardware, where the process model models a chemical process, where the process model indicates components of the chemical process, and where the components include a first component corresponding to a first feed and a second component corresponding to a second feed; finding a first tangent plane distance (TPD) value of Gibbs energy of the chemical process based on a thermodynamic model; and generating a TPD estimation function based on the first TPD value.

### BACKGROUND

### 1. Field

Embodiments and examples relate to efficient and accurate estimation of tangent plane distance (TPD).

### 2. Description of Related Art

Thermodynamic equilibrium analysis is a widely used technique for analyzing and designing chemical processes. Finding the thermodynamic equilibrium(s), if any, of a chemical process or compound has many practical uses. For example, thermodynamic equilibrium analysis can be used for evaluating separation processes such as distillation and liquid-liquid extraction. Such processes are used in pharmaceutical production, petrochemical refinement, purification of byproducts, and so forth. Because the viability and performance of many important industrial processes may depend on thermodynamic equilibrium, tools have been devised that employ complex thermodynamic models that can provide information about the thermodynamic equilibrium of a system. For example, thermodynamic models have been used to find solutions to liquid-liquid extraction problems. However, such thermodynamic models can be slow to resolve and sometimes provide fake (impractical/impossible) solutions, which may hinder how efficiently an engineer may experiment with simulations of chemical processes.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In in general aspect, a method is performed by a computing device that includes storage hardware and processing hardware, the storage hardware stores instructions configured to cause the processing hardware to perform the method, the method includes: accessing a process model stored in the storage hardware, the process model modeling a chemical process, the process model indicating components of the chemical process, the components including a first component corresponding to a first feed and a second component corresponding to a second feed; finding a first tangent plane distance (TPD) value of Gibbs energy of the chemical process based on a thermodynamic model; and generating a TPD estimation function based on the first TPD value.

The chemical process may be modeled by the process model includes a liquid-liquid extraction process.

The generating the TPD estimation function may include determining coefficients of a polynomial that fit the polynomial to the first TPD value.

The finding the first TPD value of Gibbs energy of the chemical process may include finding a solution to the thermodynamic model for the first component or the second component.

The method may further include determining a first minima of the TPD estimation function and a second minima of the TPD estimation function, the first and second minima including estimates of thermodynamic equilibria of the chemical process.

The method may further include, based on the first and second minima of the TPD estimation function, determining that the first component and the second component are immiscible.

The first and second minima may be determined by sampling the TPD estimation function over a mixture domain of the first component with the second component, the mixture domain including different ratios of the first component to the second component.

The generating the TPD estimation function may include parameterizing a mixture domain of the first component and the second component with a single variable.

An approximate solution to the chemical process of the process model may be determined through the TPD estimation function.

The approximate solution may be used as an initial condition for running a simulation of the thermodynamic model, and the simulation may converge on a solution to the chemical process that corresponds to the approximate solution.

In another general aspect, a computer-readable storage medium stores instructions that form a chemical process simulator application, wherein execution of the instructions by one or more processors causes the one or more processors to: receive, via a user interface of the chemical simulator application, one or more user inputs that select or define a chemical process model, the chemical process model indicating a composition of an effluent as including a first liquid and a solute dissolved in the first liquid, the chemical process model also indicating a composition of a solvent; generate a TPD estimation function based on a solution of a thermodynamic model as applied to the chemical process model; and generate a TPD estimation curve by sampling the TPD estimation function over for respective different ratios of first liquid relative to the second liquid.

The generating the TPD estimation function may include solving for coefficients of a polynomial.

The instructions may be further configured to cause the one or more processors to generate the estimated TPD curve over a mixture domain with values between 0 and 1, wherein each value in the mixture domain corresponds to a different ratio between the first liquid and the second liquid.

The instructions may be further configured to cause the one or more processors to determine that the first component and the second component are immiscible based on the estimated TPD curve.

The instructions may be further configured to cause the one or more processors to determine a composition of a first liquid phase and a composition of a second liquid phase based on the estimated TPD curve and/or the TPD estimation function.

The instructions may be further configured to cause the one or more processors to: initialize the thermodynamic model according to the estimated TPD curve and/or the TPD estimation function; and run a simulation of the initialized thermodynamic model to determine the composition of the first liquid phase and to determine the composition of the second liquid phase.

Generating the TPD estimation function may include determining, based on the thermodynamic model, a first TPD value corresponding to the first component, determining, based on the thermodynamic model, a second TPD value corresponding to the second component, and determining coefficients of an N-th order polynomial based on the first TPD value and the second TPD value, wherein the TPD estimation function includes the N-th order polynomial.

A final solution to the chemical process may be determined based on the TPD estimation function and based on the thermodynamic model.

The instructions may be further configured to cause the one or more processors to: determine a second TPD estimation function corresponding to a combination of the first liquid and the solute; determine a third TPD estimation function corresponding to a combination of the second liquid and the solute; and determine a solution to the chemical process model based on the TPD estimation function, the second TPD estimation function, and the third TPD estimation function.

In another general aspect, a computing device includes: one or more processors; and memory storing instructions configured to cause the one or more processors to: access a definition, stored in the memory, of a liquid-liquid extraction process, the definition defining a first liquid, a second liquid, and a solute; find a first TPD value based on a thermodynamic model applied to the liquid-liquid extraction process; and determine an estimated TPD curve or function for the first liquid and the second liquid based on the first TPD value and/or based on parameterizing a mixture domain of the first liquid and the second liquid into a single variable.

The single variable may include a blending-alpha that indicates a ratio between first liquid and the second liquid.

The blending-alpha may be equal to the composition of the first liquid, the composition of the second liquid may be proportional to a difference of the blending-alpha and a ratio of a first feed composition to a second feed composition, and the first feed composition including the first liquid and the second feed composition may include the second liquid.

The instructions may be further configured to cause the one or more processors to determine a polynomial that approximates TPD of the thermodynamic model.

The instructions may be further configured to cause the one or more processors to compute the estimated TPD curve by sampling the polynomial.

Other features and aspects will be apparent from the following detailed description, the drawings, and the claims.

### BRIEF DESCRIPTION OF THE DRAWINGS

FIG. 1 shows an example of a physical liquid-liquid extraction system, according to one or more embodiments.

FIG. 2 shows an example chemical process simulator application, according to one or more embodiments.

FIG. 3 shows a process for estimating a solution to a model of a liquid-liquid extraction process, according to one or more embodiments.

FIG. 4 shows a first thermodynamically modeled TPD function and a corresponding first TPD estimation function over a mixture domain (x-axis) of water-DIPE ratios, according to one or more embodiments.

FIG. 5 shows a second thermodynamically modeled TPD function and a corresponding second TPD estimation function over a mixture domain (x-axis) of water-acrylic acid ratios, according to one or more embodiments. FIG. 6 shows a third thermodynamically modeled TPD function and a corresponding TPD estimation function over a mixture domain (x-axis) of acrylic acid-DIPE ratios, according to one or more embodiments.

FIG. 7 shows details of a computing device 700 according to one or more embodiments.

Throughout the drawings and the detailed description, unless otherwise described or provided, the same or like drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent in view of this disclosure.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Where operations are described, unless the context suggests otherwise, operations may be performed in varying order and may or may not be performed in parallel.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

As discussed in the Background, thermodynamic models for equilibrium analysis have practical applications in analyzing and designing chemical processes used across many industries. A common method of analyzing a chemical process is to analyze the thermodynamic properties (e.g., stability and equilibria) of its components using the tangent plane distance (TPD) function. The TPD function may be the distance between the Gibbs free energy of a phase of a composition and the tangent plane to the Gibbs free energy surface as estimated from a candidate phase composition. Although, the TPD can be used for various analyses related to thermodynamic equilibrium, techniques for estimating TPD are described herein with reference to examples of designing and simulating liquid-liquid equilibrium processes for liquid-liquid extraction. For example, liquid-liquid extraction might be preferred when liquid-vapor extraction (distillation) is not feasible or preferred. Nonetheless, techniques described herein for estimating TPD (and for using estimated TPD curves) are generally applicable to any process or analysis that uses the TPD. That is to say, methods of estimating the TPD may be used for other processes involving thermodynamic equilibrium, for example liquid-vapor extraction, distillation tower, separator, gas compressing where trace liquid phase must be detected, pump operation, pipeline simulation, heat-exchanger where phase change can happen, fluid phase that may have reaction, and phase equilibrium coexist.

To elaborate on TPD, TPD analysis (TPDA) is a rigorous optimization problem. Estimation can be considered if multiple fluid phases are in equilibrium. However, TPDA itself requires high computational time and may not be suitable, for example, in industrial simulation where scale is large and a high number of components are often involved. Therefore, instead of directly solving TPDA itself, simplified TPDA curve computation techniques (described herein) may be used to derive estimated TPDA curves that may be used for analysis between important pairs of components. Such simplified TPDA techniques may require much less computational effort that prior TPD analyses, yet still provide a high level of quality in approximating true TPDA curves.

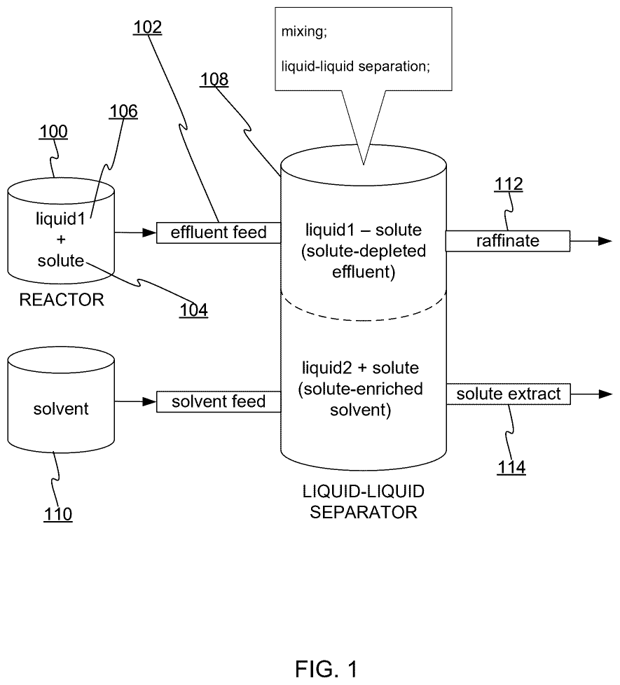

FIG. 1 shows an example of a physical liquid-liquid extraction system, according to one or more embodiments. The example system may include a reactor 100 or other source that outputs a first feed, or, effluent 102. The reactor 100 may be a system within which a reaction takes place to produce the effluent 102. The reactor 100 is only an example of an effluent source; any source of the effluent 102 may be used. The effluent 102 (or first feed) is composed of a solute 104 dissolved in a first liquid 106, as well as possibly other components. The solute 104 is the component that is the target for extraction (the component of interest). Typically, although not necessarily, the first liquid 106 and the solute 104 are polar and may be polar-bound. Water plus acrylic acid is an example effluent 102 that is referred to herein for description; in the example, water may be the first liquid 106 and acrylic acid may be the solute 104. The effluent 102 output from the reactor 100 may be fed as a first feed to a separator 108.

The separator 108 may also receive a second feed which is a solvent 110 (second liquid). Assuming a given condition (e.g., a fixed temperature and pressure, e.g., ambient), for the solvent 110 to extract the solute from the effluent 102, the solvent 110 (e.g., diisopropyl ether (DIPE)) is chosen to have a greater affinity for the solute 104 (e.g., acrylic acid) than the first liquid (e.g., water) at the given condition. In addition, for the solvent 110 to extract the solute 104 at the given condition, the solvent 110 should be chosen to be (i) immiscible with the first liquid 106 (e.g., water) at the given condition (hereafter, a constant, e.g., ambient, temperature and pressure are assumed) and (ii) of different density than the first liquid of the effluent 102. To summarize the non-limiting example, the effluent 102 may be composed of water and acrylic acid, the solvent 110 (second liquid) may be diisopropyl ether (DIPE).

The separator 108 may perform batch extraction and may include a mechanical mixer that agitates and mixes the effluent 102 and the solvent 110, creating a mixture of the feed inputs. The separator 108 may also have draw-off through-holes (or drains) placed at appropriate elevations for drawing off either of the liquid phases.

With sufficient mixing in the separator, the solvent 110, exposed to the solute 104 by the mixing, absorbs the solute 104 and thereby extracts the solute 104 from the effluent 102 (depleting the effluent 102 of the solute 104). Immiscibility of the first liquid and the second liquid, as well as the rate and total amount of transfer of solute 104 from the first liquid (of the effluent 102, e.g., water) to the solvent 110 will depend on the given condition, as well as the compositions of the solute 104, the effluent 102, and the relative densities of the liquids. These pieces of information, and others, have been computationally obtainable only by simulations that use expensive and error-prone thermodynamic models.

After mixing ceases, assuming that the second liquid (e.g., DIPE) acts as a solvent and extracts the solute 104 (e.g., acrylic acid) from the effluent 102 (e.g., water and acrylic acid), and assuming immiscibility of the first liquid (e.g., water) and the second liquid (e.g., DIPE) and a density difference therebetween, the immiscible first and second liquids (e.g., water and DIPE) separate, forming respective layers of two different liquid phases (one above the other) in the separator 108. The two liquid phases may be physically separated (e.g., drawn off according to the liquid phase layers) to produce the isolated solute-enriched second liquid (the solvent, e.g., DIPE), i.e., a liquid phase that includes the extracted solute 104 (e.g., acrylic acid). Liquid-liquid extraction may be said to have occurred. The depleted effluent 102 (the solute-depleted first liquid) may also be referred to as a raffinate 112. The solute-enriched second liquid/solvent 114 may be further processed to isolate the solute.

As noted, liquid-liquid extraction is commonly used by chemical manufacturers, pharmaceutical manufacturers, or the like, to extract a solute from a liquid. Many considerations and objectives may affect the design and configuration of a liquid-liquid extraction system for a given scenario. For example, it may be desirable to remove a sufficient amount of solute from an effluent to allow the effluent to be released into the environment or to be used for some other purpose. It may be desirable to have the transfer of solute to the solvent, and separation into two liquid phases (e.g., raffinate and solute-enriched solvent) occur within a maximum amount of time. It may be desirable to use a particular solvent (or family of solvents). It may also be desirable to minimize cost, e.g., by performing liquid-liquid extraction at ambient pressure and temperature, minimizing the number of purification/extraction stages, etc. For example, a very efficient liquid-liquid extraction might complete quickly and with high solute-transfer efficiency, which may favorable for cost. Assuming that there is separation into two liquid phases, it might be desirable for the solvent to not absorb any more than a certain amount of the first liquid (the liquid component of the effluent), or, conversely, to have the second liquid (the solvent) not absorb too much (if any) of the second liquid. In fact, after a liquid-liquid extraction, it is possible that the three components (solute and two liquids) may both exist, to varying amounts (possibly negligible) in each of the two separated liquid phases.

While liquid-liquid extraction can be an effective separation technique, configuring liquid-liquid extraction systems can be challenging in view of varying objectives and constraints. As noted above, it can be difficult to predict, for a given effluent, which solvents will extract/absorb a solute from the effluent, traits of such extraction, which solvents might be immiscible with the effluent, and what conditions might be necessary (e.g., amount of solvent, temperature, pressure, time, etc.) for both extraction and separation. In addition, it might not be possible to test, in a lab, industrial conditions under which a liquid-liquid extraction is to be used. For example, it might not be possible to produce, in a lab, the temperature or pressure under which a liquid-liquid extraction is to be industrially performed; design by experimentation might not be possible. Furthermore, it can be expensive to test candidate liquid-liquid extraction systems at-scale. A sub-optimal system might require multiple separation stages, increasing time and cost for separation.

For these reasons, and others, chemical process simulation tools (applications) have been developed to allow chemical engineers to model and simulate chemical processes such as liquid-liquid extraction. Such simulation tools may be useful for performing liquid-liquid extraction analysis. In a scenario with complex physical, cost, and or time requirements, finding an ideal solution may require a user to repeatedly reconfigure a chemical process model and re-run simulations thereof to test feasibility and effectiveness. However, as described below, prior simulation tools have shortcomings that inhibit their use in rapidly exploring and evaluating thermodynamically sensitive chemical processes.

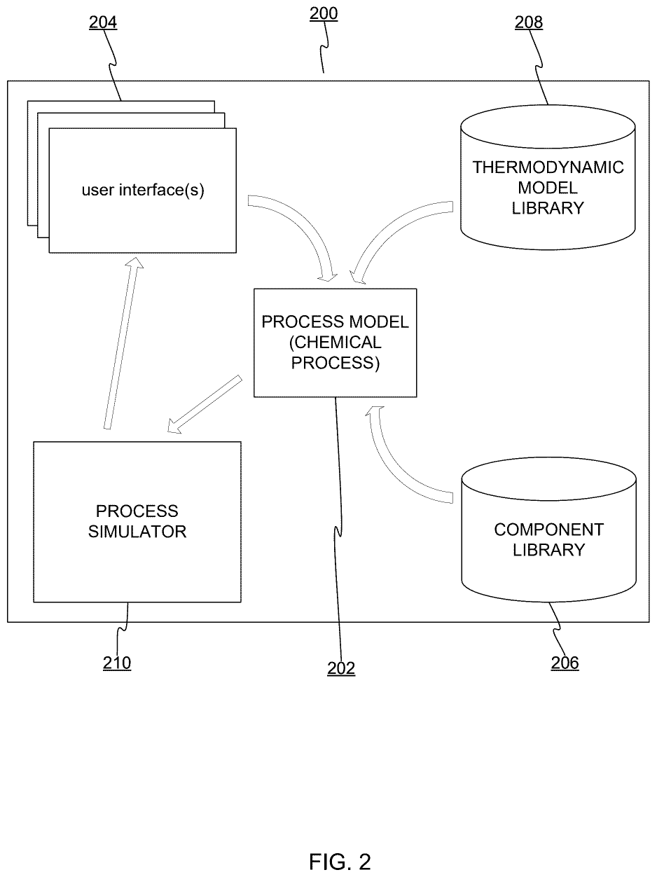

FIG. 2 shows an example chemical process simulator application 200, according to one or more embodiments. Examples of simulator applications 200 include the Advanced Simulation Library, Aspen HYSYS™, CADSIM Plus™, PRO/II™, and so forth. The simulator application 200 may include elements to enable a user to interactively configure a model 202 of a chemical process. For example, the process model 202 may be configured using one or more user interfaces 204. The user interfaces 204 may include a design surface on which the process model 202 is interactively constructed, for example, by dragging and dropping component representations of physical components from a component library 206 or tool template. Such a process may be guided by various design “wizards”. For example, a user might drag (instantiate) a reactor representation, specify an effluent output by a reactor, add a mixing chamber (e.g., for liquid-liquid extraction), configure feeds to the mixing chamber (e.g., an effluent feed and a solvent feed), specify details of the effluent (e.g., composition, temperature, amount(s), etc.), operating conditions, and so forth. A user interface may, for example, be used to select a thermodynamic model from a thermodynamic model library 208. Users from different industries (refinery, chemical, etc.) might choose different thermodynamic models to suit the processes they are interested in. In an example, the process model 202 may correspond to the liquid-liquid extraction example of FIG. 1. That is to say, the process model 202 may schematically mirror the information shown in FIG. 1. To reiterate, there are many thermodynamic models available, many of which are suited for particular processes. For example, non-random two-liquid mode (NRTL) is a suitable model for liquid-liquid separation, and the Peng-Robinson equation of state is well-suited for gas-processing.

When the process model 202 has been configured, the user may initiate simulation of the process model 202 by a process simulator 210. The process simulator 210 may parse the process model 202 and simulate performance of the process model 202, which may involve simulating basic material flow and conditions, as well as executing the selected thermodynamic model according to starting conditions specified in the process model 202. The process simulator 210 may provide outputs and results of the simulation through another of the user interfaces 204 (results may also be stored to memory, for example). For example, for liquid-liquid extraction, chemical process simulators may generate and display estimates about whether a solution converged (whether there is a solution to the thermodynamic model), whether two immiscible liquid phases will occur, how long separation might take, and/or estimates of the material composition of the solute-depleted raffinate and of the solute-enriched solvent.

While liquid-liquid extraction can be simulated with various thermodynamic models, such thermodynamic models have shortcomings. As noted above, it may be desirable for an engineer to use a chemical process simulator application to rapidly model and test different chemical processes to evaluate viability, cost, satisfaction of requirements, etc. However, thermodynamic models are complex and compute-intensive. Simulating a liquid-liquid extraction process through a thermodynamic model may require many hundreds or thousands of flash calculations to reach a solution (if any) of the thermodynamic model, because generally a search of the full solution space is needed. It's possible for some simulations to take an entire day to complete. Not only is it slow and compute-intensive to simulate the thermodynamics of a modeled candidate liquid-liquid extraction process, but also, because thermodynamic models are complex systems of mathematical equations, it is possible for a thermodynamic model to converge on a solution that mathematically solves the chemical process being simulated/modeled, and yet that solution might not be a real solution. For example, thermodynamic models may converge to solutions that are mathematically correct and yet are not actual solutions (e.g., are not physically possible). As a simple example,-1 may be a solution to X\hat{ }2=1, however, a negative solution might be a physical impossibility. As another example, a solution to a thermodynamic model might converge on a local minima and incorrectly miss a global minimum. Such mathematically correct solutions, sometimes called fake solutions, may not be actual solutions because they might involve a physical impossibility, a triviality, etc.

To summarize, thermodynamic modeling (e.g., to find equilibria) of a chemical process such as, for example, liquid-liquid extraction, is a powerful technique for predicting outcomes and finding solutions. However, such thermodynamic models are slow to solve, sensitive to initial conditions, and prone to wastefully converging on fake solutions, which makes it difficult for a user to iteratively design a process by repeatedly varying running different trial simulations. It may be desirable to obtain some of the benefits of thermodynamic modeling, for example, the ability to estimate a solution to a liquid-liquid extraction problem, while avoiding some of the aforementioned disadvantages of thermodynamic models.

The use of thermodynamic models to analyze various chemical processes such as liquid-liquid extraction processes may be improved by providing a fast estimate of a thermodynamic model (or a solution thereof), and specifically, a fast tangent plane distance (TPD) estimate function that reduces the reliance on complex thermodynamic models.

To elaborate on the relationship between thermodynamics and processes such as liquid-liquid extraction, consider that phase splitting due to thermodynamic instability of liquid mixtures is central to simulation and design problems of separation by liquid-liquid extraction (as well as by distillation). Determining the exact number of phases in a stage can help with the mathematical stability of phase equilibria predictions and related conclusions. A fast and accurate way of enabling stability analysis for fluid mixtures in any number of components and phases has been elusive. Stability analysis based on the TPD with respect to the Gibbs energy of a mixing surface has been used. This distance, referred to as the TPD function, can be analyzed to predict equilibria and other information about a modeled chemical process such as a liquid-liquid extraction. When the distance is negative then a mixture becomes unstable and splits into two liquid phases. Put another way, the TPD function is the difference between the Gibbs free energy of a phase with composition x and the tangent plane to the Gibbs free energy surface estimated from a candidate phase composition z. However, solving the TPD function has typically required the solution of complex systems of nonlinear equations (thermodynamic models) obtained with activity coefficient models or equations of state. As previously noted, such prior approaches can take a long time to complete and can converge on fake solutions, which limits the effectiveness of process simulation tools/applications at finding solutions.

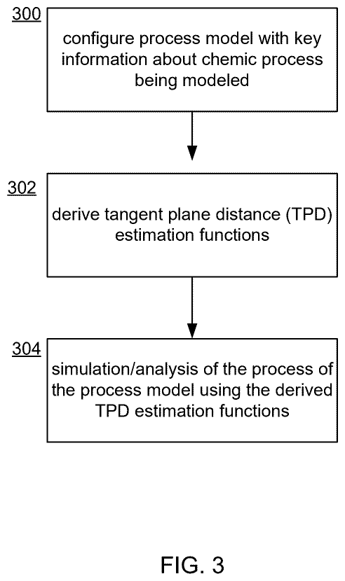

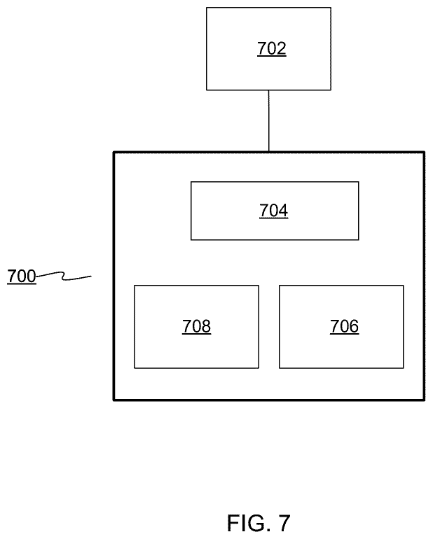

FIG. 3 shows a process for estimating a solution to a model of a liquid-liquid extraction process, according to one or more embodiments. As described later, the process may be performed by any of a variety of computing devices (e.g., the electronic device 700 of FIG. 7). Furthermore, the process may be embodied in a chemical process simulator application (e.g., chemical process simulator application 200) executing on a computing device. Such a simulator application may be in the form of instructions/code executable by one or more processors.

A configuration process 300 may be performed to configure a process model (e.g., process model 200). The process model includes information about the chemical process (e.g., liquid-liquid extraction) for which a solution or analysis is sought. The process model may include information stored in memory that describes or identifies the key components, for example, an effluent feed (and its composition, e.g., water and acrylic acid) and a solvent feed (e.g., DIPE). The process model may also specify a temperature and pressure. A least amount of information that should be included in the process model may be inferred from the techniques described below for deriving a TPD estimation function. The process model may designate a compute-intensive thermodynamic model (e.g., a large system of complex equations). The process model might also specify quantities of the key components. The process model might also specify the physical equipment of the modeled process and the configuration/arrangement thereof (e.g., reactors, mixers/separators, pipes, heaters/coolers, etc.). As an alternative to a user interactively configuring the process model using user interfaces of the simulator application, the process model may instead be pre-configured and interactively selected for simulation. However, much of the above-mentioned information is optional, and the process model may include a minimum of information that might be needed to enable an analysis of the thermodynamic process it models (e.g., a liquid-liquid extraction process).

An estimation process 302 is then performed for the modeled process This may include the simulator application deriving TPD estimation functions of respective combinations (e.g., pairs) of the key components of the modeled process; such pairs may be referred to as component pairs. In some embodiments, for a given component pair, the corresponding TPD estimation function may be a polynomial (e.g., a Taylor polynomial) that approximates the TPD of the expensive thermodynamic model. A polynomial may be derived based at least in part on one or more select TPD values obtained via the thermodynamic model (e.g., TPD values of the feed components). Derivation of such a polynomial is described below. As with a TPD function/curve obtained through a computationally demanding thermodynamic model, a polynomial TPD estimation function of a corresponding component pair (e.g., component1 and component2) may map (i) points in a domain of relative mixture ratios of the corresponding pair of components (e.g., from 100% component1, to 50/50 component1/component2, to 100% component2) (ii) to respectively corresponding points in the range, i.e., TPD values (albeit estimated by a polynomial). Such a domain may also be referred to as a mixture domain and generally may be the domain [0, 1], where the values from 0 to 1 are different ratios (mixtures) of the corresponding two components.

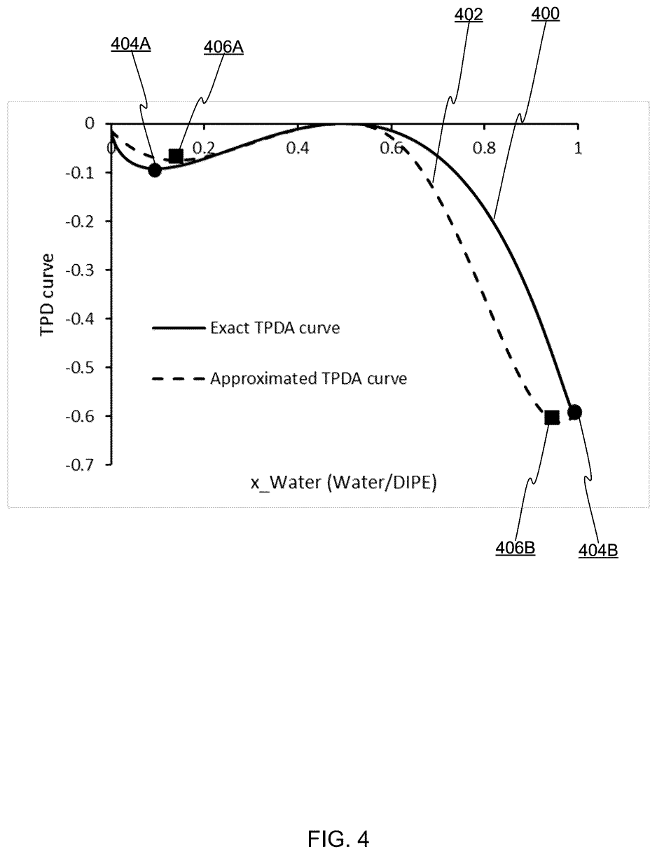

As noted, TPD estimation functions may be derived for respective pairs of key components specified in the process model. However, there are some applications/scenarios where a single TPD estimation function might be derived, for example, when there is only interest in the thermodynamic equilibrium of a single component pair. For example, a user might wish to find out only whether the two liquids of a liquid-liquid extract process are immiscible as per the conditions of the process model. Thus, although multiple TPD estimation functions for different respective component pairs are practical and are mainly described herein (see, e.g., FIGS. 4-6), a single TPD estimation function (for example, FIG. 4) may be derived and practically applied. Referring to the water-DIPE-acrylic acid example, only the first TPD estimation function of FIG. 4 might be obtained for the purpose of determining miscibility, for example.

Still referring to FIG. 3, a next stage of the solution estimation process may include the simulator application performing a simulation or analysis 304 of the process model using the previously derived TPD estimation functions. Such analysis 304 may involve determining and evaluating various features of the TPD estimation functions (the functions, and their curves, may sometimes be used interchangeably). For example, each TPD estimation function may be uniformly sampled over its domain with sufficient density. With such a numeric representation (curve) of each TPD estimation function, numerical analysis may be performed to identify estimated TPD features such as estimated local minima/maxima, estimated global minimum/maximum, curvature features, positive/negative values, and so forth. Known techniques of analyzing a TPD function may be used (typically, using numerical analysis). Such analysis may reveal whether two liquid components are immiscible (whether there will be two liquid phases), what will be the composition of the two liquid phases, how long will separation take, and/or the like. Moreover, because the TPD estimation functions can provide an estimated non-fake global solution (to the process modeled by the process model) that is somewhat close to the actual solution, the estimated solution provided by the TPD estimation functions can be used to initialize the process model's expensive-but-accurate thermodynamic model (starting the thermodynamic model at the estimated solution). Then, the thermodynamic model can be executed to find a highly accurate solution to the process model (which should be close to the starting condition, i.e., the estimated solution). The use of the estimated solution as a starting condition of the thermodynamic model can also help prevent the thermodynamic model from converging on a fake solution (since the estimated solution is near the real solution). In addition, because the thus-initialized thermodynamic model begins simulation already close to the actual solution, the execution time of solving the compute-intensive accurate thermodynamic model may take significantly less time as compared to solving the thermodynamic model over the entire space of possible solutions.

Techniques for obtaining TPD estimation functions based on a process model for liquid-liquid extraction are described next with reference to the example of acrylic acid extraction from water using DIPE, as shown in FIGS. 4-6. However, the techniques are not limited to liquid-liquid extraction or the example thereof.

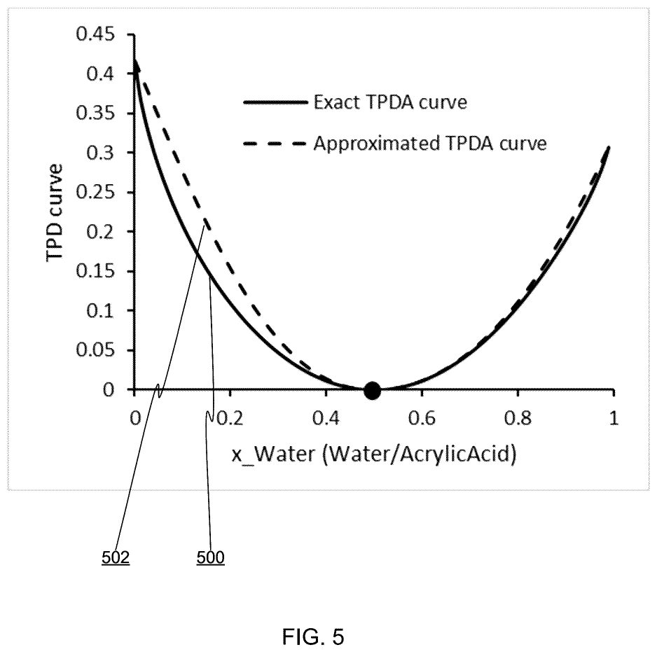

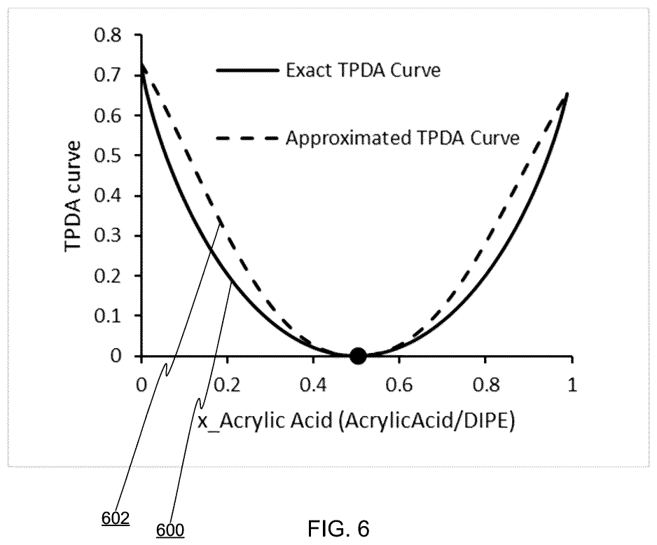

In each of FIGS. 4-6, the solid lines represent respectively corresponding thermodynamically modeled TPD functions (computationally expensive), and the dashed lines represent respectively corresponding TPD estimation functions (computationally cheap). FIG. 4 shows a first thermodynamically modeled TPD function 400 and a corresponding first TPD estimation function 402 over a mixture domain (x-axis) of water-DIPE ratios (pure DIPE is on the left and pure water is on the right), according to one or more embodiments. FIG. 5 shows a second thermodynamically modeled TPD function 500 and a corresponding second TPD estimation function 502 over a mixture domain (x-axis) of water-acrylic acid ratios (pure DIPE is on the left and pure acrylic acid is on the right), according to one or more embodiments. FIG. 6 shows a third thermodynamically modeled TPD function 600 and a corresponding TPD estimation function 602 over a mixture domain (x-axis) of acrylic acid-DIPE ratios (pure DIPE is on the left and pure acrylic acid is on the right).

In one or more embodiments, an efficient solution algorithm may include obtaining parameterized TPD functions (TPD estimation functions) which approximate the TPD analysis problem and which can identify the liquid key components without incurring the computational overhead of repeatedly solving a complex thermodynamic model. More specifically, for a given process model (e.g., modeling a liquid-liquid extraction), the TPD problem may be solved by identifying component pairs (e.g., water-DIPE, water-acrylic acid, and DIPE-acrylic acid) and executing curvature analysis on the parameterized TPD curves (TPD estimation functions). Assuming that the process model identifies n components, the number of component pairs can be reduced from n*(n−1)/2 to approximately n−1. To elaborate, one major liquid key component may be identified based on its thermodynamic properties. For example, if water exists with a significant amount, then water may be selected as the major aqueous phase key, or if water is not present, or the amount was neglectable, then the liquid with the lowest TPD value at near pure condition may be chosen as the major liquid key component. With the major liquid key component established, it may then be paired with other liquid-like components (gas-like components such as N2, O2 . . . can be excluded). This leads to the total count of the component pairs being reduced to less than or equal to n−1.

After the major liquid key has been identified through curvature analysis, the second major liquid key component may be identified. To that end, each of the n−1 (or less) component pairs may have its corresponding parameterized TPD (TPD estimation function) subjected to curvature analysis. The result of such curvature analyses may identify one group of liquid components that are immiscible with the major liquid key, and another group of liquid components that are miscible with the major liquid key. The second major liquid key is then found from within the first group. With the two major liquid keys identified, they may be assigned as the leading components in each of the liquid phases.

In some embodiments, for curvature analysis (or other purposes), each component pair's respectively corresponding TPD estimation function (parameterized TPD formula) may be obtained by finding an N-th order (e.g., 4-th order) polynomial which is constructed to fit the thermodynamics of the overall feed composition of the corresponding component pair. The polynomial may be a Taylor polynomial. With such a 4-th order polynomial to serve as a proxy for a full thermodynamic model simulation (providing a reasonably estimated TPD curve), the computational expense in identifying the curvatures that indicate potential liquid-liquid separation is significantly reduced. The approximation itself, however, is of high quality as compared to the exact TPD curve.

To understand how 4-th order polynomials (TPD approximation functions) of respective component pairs are derived, consider first the foundation in thermodynamics. Equation 1 denotes a Gibbs energy function for a composition x:

$$g ( x ) = f ( x , T , P ) \qquad Equation 1$$

Here, x is the composition, and Temperature (T) and pressure (P) are presumed constant. f( ) is a shorthand notation for a complex thermodynamic model (e.g., a complex system of equations). That is, f( ) is expensive to compute. However, at the effluent feed, for example, x=z. That is, x=z denotes the effluent composition, which is known (e.g., defined by the process model). However, since the composition of x=z is known, g(z) can be readily obtained from the thermodynamic model. For any x other than z (when x≠z), g(x) is difficult to compute as it would involve finding a solution for a thermodynamic model.

Regarding g(z), z can potentially be in a high dimension. For example, for a two-component system, there may be 2 z values, but each value can be a real value between (0,1), so the combinations of z values is unlimited. Also, T and P can be different as well. So g(z) should be solved at least once for each different TPz combination. Once g(T, P, z) is calculated, the remaining work is to solve x (there are 2× values in a two-component system). The example referred to herein, using the simplified TPDA approach, is a two-component system. However, if, for example, there are 10 components, then in principle, there may be 45 (10*9/2) pairs of two-component subsystems for which the simplified TPDA approach can be used to find a solution (and the method is efficient to do so). However, the pairs can be reduced to 9 pairs if one of the key component is water, for example.

Equation 2 relates the Gibbs energy function to the TPD thereof.

$$t ( x ) = g ( x ) - Line ( x , z ) Line ( x , z ) = g ( z ) + {\sum }_{i = 1}^{3} ( {x}_{i} - {z}_{i} ) \frac{\partial g}{\partial z i} \qquad Equation 2$$

In equation 2, t(x) represents a precise thermodynamically modeled TPD function, i.e., the distance between g(x) and the tangent plane, i.e., Line(x, z). This t(x) corresponds to the solid curves in FIGS. 4-6, is computationally expensive to obtain, and may not guarantee a real (non-fake) solution. However, the t(x) of a thermodynamic model is generally accurate and may be considered to be a ground truth against which a TPD estimation function may be compared.

Because of the noted problems with t(x) (i.e., conventional TPD), an N-th order (e.g., 4-th order) polynomial may be found that sufficiently approximates t(x) for the given process model, as shown in Equation 3.

$$t ( α ) = t ( {z}_{k} ) + {c}_{1} ( α - {z}_{k} ) + {{c}_{2} ( α - {z}_{k} )}^{2} + {{c}_{3} ( α - {z}_{k} )}^{3} + {{c}_{4} ( α - {z}_{k} )}^{4} \qquad Equation 3$$

Here, for the polynomial \tilde{t}(α), α is a parameterization of the composition domain, as shown by Equation 4. Also, “k” stands for “key”.

Regarding t(zₖ), t(zₖ)=0, because t(x)=g(x)−[g(z)+sumᵢ (xᵢ−zᵢ)*DgDzᵢ. If x is replaced with z inside t(x), then t(z)=g(z)−[g(z)+sumᵢ (zᵢ−zᵢ)*DgDzᵢ=0. Note that t(zₖ) is shown as kept on the right-hand-side of equation (3) to show that this is a forth order polynomial with a leading term t(zₖ).

$$\{ \begin{matrix}{x}_{k e y} = α \\ {x}_{i \neq k e y} = ( 1 - α ) \frac{{z}_{i}}{1 - {z}_{k e y}}\end{matrix} \qquad Equation 4$$

In Equation 4, there are two components x_{key} and x_{i≠key}. x_{key} is defined as α, and x_{i≠key} is defined as a function of α, zᵢ, and z_{key}, where z_{key} is the known feed composition of the major key component of the current component pair (e.g., the effluent water-acrylic acid), and where zᵢ is the known feed composition of the other component of the component pair (e.g., solvent DIPE).

As can be seen, in Equation 3, the TPD approximation function \tilde{t}(α), has α as its only independent variable. With the change of α from 0 to 1, the composition x_{key} is fully defined within the [0, 1] domain. Moreover, several points of \tilde{t}(α) may be solved-for as a function of a (e.g., the two equivalencies in Equation 4). Furthermore, the approximated 4-th order polynomial has a total of four coefficients, with the leading coefficient c₁ known to be zero. Thus, only three coefficients (c₂, c₃, c₄) remain to be solved. Since the near-pure Gibbs energy values are known (or computable) for each component in the component pair, and because the compositional derivative at near-pure can also be approximated, then the 4-th order polynomial is fully defined and can be represented by only the three coefficients c₂, c₃, c₄, which can be readily solved-for given the aforementioned knowns and single-variable parameterization of the mixture domain; solutions for the 40th order single-variable can be solved analytically without the need for iteration analysis.

Further regarding deriving a \tilde{t}(α) for a component pair (two-component mixture), the TPD approximation function \tilde{t}(α) only needs three coefficients c₂, c₃, and c₄; as noted, c₁=0, which is because the rigorously calculated TPD has a zero value first order derivative at the feed z. Thus, three rigorously-calculated TPD points t(α) may be all that are needed for polynomial fitting. Two such points are the near-pure (α→0 and α→1) TPD values for the respective two components (i.e., t(α→0) and t(α→0)). A third such point is the first order derivative of

$$\frac{d t ( α )}{d α}$$

as α→1. This third quantity, however, can be approximated as

$$\frac{d t ( α )}{d α} = max ( 1 , 1 + t ( α \to 1 ) )$$

because the rigorously calculated

$$\frac{d t ( α )}{d α}$$

as α→1 would be a large positive value. Accordingly, max(1,1+t(α→1)) may be used to prevent over-fitting.

To summarize, for a component pair currently being processed, assuming that suitable coefficients are found, the corresponding TDP approximation function of Equation 3 (\tilde{t}(a)) can be solved for any value of alpha from [0,1] (the mixture domain), based on the compositions of the components in the component pair currently being processed. A TPD approximation function (I (a)) may be found for each of the other n−1 component pairs (with different coefficients and x_{i≠key} values).

The technique described above is readily applicable to any multi-component mixture multi-liquid phase equilibrium, regardless of which thermodynamic model is applied. In some embodiments, for a mixture where the component count is greater than two, c₂ can be rigorously calculated as

$$\frac{1}{2} \frac{{d}^{2} t ( α )}{d {α}^{2}}$$

as α=z_{key}. As result, the remaining c₃, and c₄ can be fitted by the rigorously calculated t(α) and

$$\frac{d t ( α )}{d α} = max ( 1 , 1 + t ( 1 ) )$$

as α→1, or by rigorously calculated values of t(α→0) and t(α→1), depending on system requirements.

Regarding selection of key components as discussed above, if water exists with a significant amount, then water may be deemed to be the major aqueous phase key. However, if water is not present (or in a negligible amount), then the component pair with the lowest TPD value at near pure condition may be chosen.

Turning to the example of FIGS. 4-6, FIG. 4 shows a first thermodynamically modeled TPD function 400 (solid line, i.e., t(x)) and a corresponding first TPD estimation function 402 (dashed line, i.e., \tilde{t}(α)) over a domain of water-DIPE ratios (pure DIPE is on the left and pure water is on the right), according to one or more embodiments. FIG. 4 corresponds to the water-DIPE component pair. The first thermodynamically modeled TPD function 400 was obtained by running full thermodynamic simulation and is provided as a ground-truth against which to compare the first TPD estimation function 402. As can be seen, the curve of the TPD estimation function 402 closely mirrors the ground-truth thermodynamically modeled TPD function 400 and may obviate the need to solve the thermodynamically modeled TPD function 400 over the entire mixture domain. That is, the curves are close in key features such as magnitudes, curvatures and inflection points (minima/maxima). For example, estimated minima 404A and 404B are close to ground-truth minima 406A and 406B. Furthermore, in the specific example of the [0,1] water-DIPE mixture/ratio domain represented in FIG. 4, it can be seen from the two minima that two liquid phases will form after mixing(i.e., the two components are immiscible) under the presumed feed compositions (input effluent and input solvent) and conditions (e.g., T and P). In other words, the dashed line in FIG. 4 shows the values generated by the 4-th order polynomial (first TPD estimation function, or \tilde{t}(α)) that was derived for the water-DIPE mixture/ratio domain. The coefficients of the first TPD estimation function may be obtained as described above for the known component pair of water and DIPE.

Regarding analysis of curve features of FIG. 4, known TPD curve analysis techniques may be used. Regarding known TPD curve analysis techniques, consider that a TPD curve has one or more minimums, each of which may represent a potential phase in equilibrium. If there is only one minimum, it indicates that there is no multi-phase in equilibrium, i.e., the stable solution is just one phase. However, if there is more than one minimum, then there might be two or more phases in equilibrium. However, the effort to find all the minimums is almost impossible in practice. Therefore, the overall TPDA curve can be simplified into several simplified TPDA curves, each of which represents a pair of components selected from the overall components.

FIG. 5 shows a second thermodynamically modeled TPD function 500 and a corresponding second TPD estimation function 502 over a [0, 1] mixture domain of the ratio of water to acrylic acid (pure water is on the right and pure acrylic acid is on the left), according to one or more embodiments. FIG. 5 corresponds to the water-acrylic acid component pair. The second TPD estimation function 502 (a second \tilde{t}(α)) may be derived (e.g., polynomial coefficients determined) based on the feed compositions of the corresponding component pair (e.g., acrylic acid and water). Again, the second TPD estimation function 502 is a close approximation of the compute-intensive ground-truth second thermodynamically modeled TPD function 500 for the same component pair.

FIG. 6 shows a third thermodynamically modeled TPD function 600 and a corresponding third TPD estimation function 602 over a mixture domain of acrylic acid-DIPE ratios (pure DIPE is on the left and pure acrylic acid is on the right), according to one or more embodiments. FIG. 6 corresponds to the acrylic acid-DIPE component pair. The third TPD estimation function 602 (a third \tilde{t}(α)) may be derived (e.g., polynomial coefficients determined) according to the feed compositions of the corresponding component pair (e.g., acrylic acid and DIPE). Again, the third TPD estimation function 602 is a close approximation of the expensive ground-truth third thermodynamically modeled TPD function 600.

The curvatures of the second and third TPD estimations functions 502 and 602 both indicate that the solute (acrylic acid) is miscible with each of the liquid components (water and DIPE). Also, by comparing the second TPD estimation function 502 with the third TPD estimation function 602 it can be concluded that the solute (acrylic acid) has greater affinity to DIPE and DIPE should extract at least some of the solute from the water/effluent. To elaborate, if the simplified TPD curve for DIPE and acrylic acid shows curvature, then it means there might be two liquid phases in equilibrium. If there is no curvature, meaning there is only one minimum on this simplified TPD curve, then the two components are miscible, and no multiple phase equilibrium can happen. Without the estimated-TPD curvature analysis from FIGS. 4-6, a fake solution where the first liquid phase is dominated by DIPE and the second liquid phase is dominated by water and acrylic acid could be converged-to by the thermodynamic model, as opposed to the true solution where there should be a significant amount of acrylic acid extracted out from the aqueous phase into the other liquid phase (the solvent, e.g., DIPE).

As shown, curvature analysis on curves generated based on polynomial coefficients gives a highly accurate prediction of liquid-liquid separation, for example. Usually, such separation is indicated by a value of x (e.g., x_{water}) that stays in between the two values (minima) of x in the final solution of the respective two liquid phases that are in equilibrium, which may be referred to as the xLLSplit point. As described next, if there is only one liquid phase in the final solution (there is no liquid-liquid separation), then the value of the xLLSplit point may help to indicate whether the remaining liquid phase is liquid 1 phase or liquid 2 phase (i.e., if it is the top or bottom liquid phase).

More specifically, xLLSplit may be used to determine, in the case where an estimated TPD curve is “U” shaped (indicating miscibility) and not “W” shaped (which would indicate immiscibility), whether the minimum represents liquid1 or liquid2. In other words, if the mixture changes (e.g., there is a temperature or pressure change), it is possible that one liquid disappears, and there may be a question as to which liquid disappears. In a practical sense, this may not be significant, however, for purposes of fully simulating a modeled chemical process, it may be helpful to determine if the disappearing liquid was the top liquid phase or the bottom liquid phase. Referring to FIG. 4, left minima (e.g., point 404A) has less density and the rightward minima (e.g., point 404B) has more density (left is on top), and two liquid phase layers are formed in the container (the bottom layer is water-rich liquid2). However, when the condition changes (e.g., temperature changes) the top layer could disappear, resulting is just one liquid phase-a water-rich liquid phase. So, referring to the example, it may be desirable to know whether the singe liquid phase in the container is the water-rich phase.

The xLLSplit point may be the x value at the midpoint, in the mixture domain, between the two minima (e.g., points 404A and 404B) of the first TPD estimation function 402, where on left of the middle is liquid1 and on right is liquid2. FIG. 4 shows distinct liquid phases of liquid1 and liquid2. However, if that were not the case, then, if the minima of FIG. 5 were on the right of the xLLSplit point, then FIG. 5 would represent liquid2. However, if the minima were on left of the xLLSplit point then FIG. 5 would represent liquid1.

In addition to high-level conclusions that can be obtained from TPD estimation for a chemical process that depends on thermodynamic equilibrium (e.g., liquid-liquid separation), the estimation techniques described above can also be used to provide reasonably accurate estimated phase compositions that are close to the actual end equilibrium compositions (as would be found by a fully solved thermodynamic model). In other words, the composition at equilibrium composition, which may be a final goal of a user, can be estimated. Once the a values are known, x_{key} values can be obtained from Equation 4, and from those it is possible to calculate the compositions of all of the not-key components using Equation 3.

The TPD estimation techniques described herein may enable new algorithms. For example, because an estimated solution can be obtained rapidly (without full thermodynamic model simulation), it is possible to automate searching a solution space. For example, an iterative simulation may be constructed where one or more parameters of the modeled process are incrementally varied. Each iteration may include testing an estimated property or value (e.g., a curve property or a composition) against a test condition. Because each iteration does not require a full thermodynamic model simulation, each iteration can be completed quickly, enabling empirically searching for a solution through using TPD estimations for the iterations.

While mathematical notation is used herein to describe various embodiments and techniques, it will be appreciated that the mathematical notation is a convenient language for efficiently and accurately describing, at a high level, the operations of a computing device (e.g., computing device 700 in FIG. 7). The mathematical notation and language used herein can be readily used to configure code that can be compiled to generate machine instructions that can be executed by one or more processors of a computing device. It will be further appreciated that the expensive thermodynamic models previously used to compute complete TPD curves are too complex and compute-intensive to be practically performed by the human mind, even with the aid of paper and pencil. Similarly, computing an estimated TPD curve from a TPD estimation function is not practically performed manually, as this also involves many precise (e.g., floating point) operations; if performed manually, such computations would be impractically slow and of course would undesirably not be available within the context of a chemical process simulator application. Furthermore, the techniques described herein have practical material applications. For example, curvature analysis (or a deduction thereof) may be used to configure industrial chemical processes. Moreover, because tools/applications for analyzing chemical processes are themselves useful and practical, the techniques described herein, insofar as they may improve the efficiency and accuracy of this category of software/application, stand on their own and no actual industrial or chemical activity is required for the techniques to be beneficial.

FIG. 7 shows details of a computing device 700 according to one or more embodiments. As noted previously, the technical disclosures herein suffice for programmers to write source code, and/or configure reconfigurable processing hardware (e.g., field-programmable gate arrays (FPGAs)), and/or design application-specific integrated circuits (ASICs), etc., to run on the computing device 700 to implement any of the features or embodiments described herein.

The computing device 700 may have one or more displays 702, a network interface 704 (or several), as well as storage hardware 706 and processing hardware 708. The processing hardware 708 may be a combination of any one or more: central processing units, graphics processing units, analog-to-digital converters, bus chips, FPGAs, ASICs, Application-specific Standard Products (ASSPs), neural processors, or Complex Programmable Logic Devices (CPLDs), etc. The storage hardware 706 may be any combination of magnetic storage, static memory, volatile memory, non-volatile memory, optically or magnetically readable matter, etc. Storage and processing may also be combined in hardware such as in-processing-memory type of memory. The meanings of the terms “computer-readable storage” and “storage hardware”, as used herein do not refer to signals or energy per se, but rather refer to physical apparatuses and states of matter. The hardware elements of the computing device 700 may cooperate in ways understood in the art of machine computing. In addition, input devices (e.g., for interacting with user interfaces) may be integrated with or in communication with the computing device 700. The computing device 700 may have any form-factor or may be used in any type of encompassing device. The computing device 700 may also be a cloud service, a virtual machine, or the like.

The computing apparatuses, the electronic devices, the processors, the memories, the image sensors, the displays, the information output system and hardware, the storage devices, and other apparatuses, devices, units, modules, and components described herein with respect to FIGS. 1-7 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method performed by a computing device comprising storage hardware and processing hardware, the storage hardware storing instructions configured to cause the processing hardware to perform the method, the method comprising:
accessing a process model stored in the storage hardware, the process model modeling a chemical process, the process model indicating components of the chemical process, the components including a first component corresponding to a first feed and a second component corresponding to a second feed;
finding a first tangent plane distance (TPD) value of Gibbs energy of the chemical process based on a thermodynamic model; and
generating a TPD estimation function based on the first TPD value.

2. The method of claim 1, wherein the chemical process modeled by the process model comprises a liquid-liquid extraction process.

3. The method of claim 1, wherein the generating the TPD estimation function comprises determining coefficients of a polynomial that fit the polynomial to the first TPD value.

4. The method of claim 1, wherein the finding the first TPD value of Gibbs energy of the chemical process comprises finding a solution to the thermodynamic model for the first component or the second component.

5. The method of claim 1, further comprising determining a first minima of the TPD estimation function and a second minima of the TPD estimation function, the first and second minima comprising estimates of thermodynamic equilibria of the chemical process.

6. The method of claim 5, further comprising, based on the first and second minima of the TPD estimation function, determining that the first component and the second component are immiscible.

7. The method of claim 5, wherein the first and second minima are determined by sampling the TPD estimation function over a mixture domain of the first component with the second component, the mixture domain including different ratios of the first component to the second component.

8. The method of claim 1, wherein the generating the TPD estimation function comprises parameterizing a mixture domain of the first component and the second component with a single variable.

9. The method of claim 1, wherein an approximate solution to the chemical process of the process model is determined through the TPD estimation function.

10. The method of claim 9, wherein the approximate solution is used as an initial condition for running a simulation of the thermodynamic model, the simulation converging on a solution to the chemical process that corresponds to the approximate solution.

11. A computer-readable storage medium storing instructions that form a chemical process simulator application, wherein execution of the instructions by one or more processors causes the one or more processors to:
receive, via a user interface of the chemical simulator application, one or more user inputs that select or define a chemical process model, the chemical process model indicating a composition of an effluent as including a first liquid and a solute dissolved in the first liquid, the chemical process model also indicating a composition of a solvent;
generate a TPD estimation function based on a solution of a thermodynamic model as applied to the chemical process model; and
generate a TPD estimation curve by sampling the TPD estimation function over for respective different ratios of first liquid relative to the second liquid.

12. The computer-readable storage medium according to claim 11, wherein the generating the TPD estimation function comprises solving for coefficients of a polynomial.

13. The computer-readable storage medium of claim 11, wherein the instructions are further configured to cause the one or more processors to generate the estimated TPD curve over a mixture domain with values between 0 and 1, wherein each value in the mixture domain corresponds to a different ratio between the first liquid and the second liquid.

14. The computer-readable storage medium of claim 13, wherein the instructions are further configured to cause the one or more processors to determine that the first component and the second component are immiscible based on the estimated TPD curve.

15. The computer-readable storage medium of claim 13, wherein the instructions are further configured to cause the one or more processors to determine a composition of a first liquid phase and a composition of a second liquid phase based on the estimated TPD curve and/or the TPD estimation function.

16. The computer-readable storage medium of claim 15, wherein the instructions are further configured to cause the one or more processors to:
initialize the thermodynamic model according to the estimated TPD curve and/or the TPD estimation function; and
run a simulation of the initialized thermodynamic model to determine the composition of the first liquid phase and to determine the composition of the second liquid phase.

17. The computer-readable storage medium of claim 15, wherein generating the TPD estimation function comprises determining, based on the thermodynamic model, a first TPD value corresponding to the first component, determining, based on the thermodynamic model, a second TPD value corresponding to the second component, and determining coefficients of an N-th order polynomial based on the first TPD value and the second TPD value, wherein the TPD estimation function comprises the N-th order polynomial.

18. The computer-readable storage medium of claim 11, wherein a final solution to the chemical process is determined based on the TPD estimation function and based on the thermodynamic model.

19. The computer-readable storage medium of claim 11, wherein the instructions are further configured to cause the one or more processors to:
determine a second TPD estimation function corresponding to a combination of the first liquid and the solute;
determine a third TPD estimation function corresponding to a combination of the second liquid and the solute; and
determine a solution to the chemical process model based on the TPD estimation function, the second TPD estimation function, and the third TPD estimation function.

20. A computing device comprising:
one or more processors; and
memory storing instructions configured to cause the one or more processors to:
access a definition, stored in the memory, of a liquid-liquid extraction process, the definition defining a first liquid, a second liquid, and a solute;
find a first TPD value based on a thermodynamic model applied to the liquid-liquid extraction process; and
determine an estimated TPD curve or function for the first liquid and the second liquid based on the first TPD value and/or based on parameterizing a mixture domain of the first liquid and the second liquid into a single variable.

21. The computing device of claim 20, wherein the single variable comprises a blending-alpha that indicates a ratio between first liquid and the second liquid.

22. The computing device of claim 20, wherein the blending-alpha is equal to the composition of the first liquid, and wherein the composition of the second liquid is proportional to a difference of the blending-alpha and a ratio of a first feed composition to a second feed composition, the first feed composition including the first liquid and the second feed composition including the second liquid.

23. The computing device of claim 20, wherein the instructions are further configured to cause the one or more processors to determine a polynomial that approximates TPD of the thermodynamic model.

24. The computing device of claim 23, wherein the instructions are further configured to cause the one or more processors to compute the estimated TPD curve by sampling the polynomial.
